(19) United States
(12) Patent Application Publication
(10) Pub. No.: US 2007/0134413 A1
(43) Pub. Date: Jun. 14, 2007

(54) Vapor deposition method and vapor deposition apparatus

(75) Inventors: Masayasu Futagawa, Mei (JP); Noriko Kakimoto, Nara (JP)

Correspondence Address: MORRISON & FOERSTER LLP, 755 PAGE MILL RD, PALO ALTO, CA, 94304-1018, US

(73) Assignee: Sharp Kabushiki Kaisha, Osaka-shi (JP)

(21) Appl. No.: 10/575,187

(22) PCT Filed: Sep. 29, 2004
(86) PCT No.: PCT/JP04/14201

§ 371 Date: Apr. 6, 2006

(30) Foreign Application Priority Data
Oct. 6, 2003 (JP) 2003-347134

(51) Int. Cl. B05C 11/00; C23C 16/00

(52) U.S. Cl. 427/248.1; 118/729; 118/663; 118/696

(57) ABSTRACT

A vapor deposition method is provided that can form a highly uniform epitaxial layer even under different growth conditions. The vapor deposition method uses an apparatus including the process chamber, a flow channel for supplying the reactant gas onto the substrate and discharging the reactant gas, a substrate holding portion holding the substrate, moving means for relatively moving the substrate holding portion and the flow channel, control means for controlling the moving means, and heating means for heating the substrate. Based on a set growth condition as well as the stored positional data, the control means performs control of the position of the substrate holding portion or the position of the flow channel to decrease a change in relative positions of the flow channel and the substrate.

### TECHNICAL FIELD

The present invention relates to a vapor deposition method and a vapor deposition apparatus. In particular, the invention relates to a vapor deposition method and a vapor deposition apparatus for forming a uniform epitaxial growth layer.

### BACKGROUND ART

A semiconductor manufacturing method uses, as an apparatus for forming such a thin film as oxide film, nitride film or silicon film on a surface of a substrate, a thermal CVD apparatus, a plasma CVD apparatus or an epitaxial growth apparatus for example (see Patent Document 1). FIG. 6 shows an example of an MOCVD (Metal-Organic Chemical Vapor Deposition) apparatus that has been known. This MOCVD apparatus is generally called horizontal MOCVD apparatus, because a reactant gas flows laterally and horizontally in a flow channel. The horizontal MOCVD apparatus has, as shown in FIG. 6, a process chamber 2 formed by a chamber 1 in the shape of a rectangular parallelepiped, and a flow channel 5 extending through process chamber 2. Flow channel 5 has one end provided with a gas inlet 3 and the other end provided with a gas outlet 4. Further, the flow channel has an opening 6 formed at a portion located substantially centrally of the flow channel. At opening 6, a susceptor 9 is provided. Susceptor 9 has a substrate holding member 8 holding a substrate-to-be-processed 7. In addition, under susceptor 9, a substrate heater 10 is provided for heating substrate-to-be-processed 7.

These components are arranged relative to each other in the manner that a bottom surface 20 on the inside and on the substrate holding side of flow channel 5 and a surface 21 of substrate holding member 8 are coplanar (see Patent Document 2). Further, in some cases, in a depressed portion formed in substrate holding member 8, substrate-to-be-processed 7 is mounted, and surface 21 of substrate holding member 8 and a crystal growth surface 22 of the substrate are arranged coplanar so that crystal growth surface 22 of substrate-to-be-processed 7 is also coplanar with the aforementioned coplanar surfaces (see Patent Document 3). In a film deposition process for the substrate, a reactant gas 15 is supplied from gas inlet 3 into flow channel 5 and substrate heater 10 induces a chemical reaction for film deposition on substrate-to-be-processed 7 so as to form a thin film on substrate-to-be-processed 7. Then, reactant gas 15 flowing to pass by over substrate-to-be-processed 7 is discharged from gas outlet 4.

Regarding such a horizontal MOCVD reactor as described above, for achieving high-quality and superior crystal growth, reactant gas 15 flowing through flow channel 5 has to be in the form of a laminar flow at and around substrate-to-be-processed 7 provided on high-temperature susceptor 9. Here, the laminar flow is spatially uniform in flow-velocity distribution and temperature of reactant gas 15 and has no vortex or turbulence generated in the flow of reactant gas 15. For providing such a laminar flow, any measures have to be taken for the way in which reactant gas 15 is flown, for control of the temperature of the reactant gas as well as for a variety of components of the reactor for example. In particular, depending on the relative positional relation between surface 21 of substrate holding member 8 and bottom surface 20 on the inside and on the substrate holding side of flow channel 5, the flow of reactant gas 15 in the vicinity of substrate-to-be-processed 7 varies to a great degree, which has a great influence on formation of a uniform thin film. Therefore, the required precision of the relative positional relation is 0.1 mm or smaller. The positioning precision is therefore a very important matter to be addressed.

Accordingly, as a method of improving the static state in the manufacturing process, a measure is disclosed according to which heating means for example is provided upstream and in the vicinity of the susceptor for preheating the reactant gas and, an ascending air current generated by the heating is used to convert the reactant gas, which has been caused to become a turbulent flow, back into a laminar flow, and thereby provide the reactant gas in the form of the laminar flow on the substrate. An effective method is also disclosed, according to which the position where the gas is converted again into a turbulent flow is shifted further downstream so as to ensure that the laminar flow is provided on the substrate, by providing heating means as well downstream and in the vicinity of the susceptor (see Patent Document 2).

Similarly, as a method of improving the static state in the manufacturing process, a technique is disclosed according to which a tray holding the substrate is rotated while vapor deposition proceeds and the gap between the inner peripheral surface of a depressed portion where the tray is placed and the outer peripheral surface of the tray is made large on the downstream side of the reactant gas relative to the gap on the upstream side thereof. It is then disclosed that a gas generated from the depressed portion where the tray is placed is caused to flow out from the relatively large gap on the downstream side, thereby suppressing the gas flowing out from the relatively small gap on the upstream side, so as to prevent the generated gas from being taken into a growing thin film, and thus generating a high-quality wafer (see Patent Document 3).

It is also disclosed that, regarding the horizontal MOCVD apparatus, the relative positions of the substrate and the surface on the inside and on the side opposite to the substrate-mounted side of the are changed to a great degree while a thin film is formed so as to allow the substrate to be exposed to different gases alternately and thereby alternately grow different thin films (see Patent Document 4). Further, a vapor deposition apparatus is disclosed that provides a method of improving the state after the thin film is formed, having a cooling gas flow-out portion provided near the outer periphery of the susceptor for cooling the susceptor provided with such heating means as a resistance heater. It is disclosed that this apparatus can use the cooling gas to speedily lower the temperature of the susceptor and thus the throughput can be improved without deterioration in uniformity and film quality (see Patent Document 5).

Patent Document 1: Japanese Patent No. 3338884

Patent Document 2: Japanese Patent Laying-Open No. 5-283339

Patent Document 3: Japanese Patent Laying-Open No. 11-67670

Patent Document 4: Japanese Patent Laying-Open No. 5-175141

Patent Document 5: Japanese Patent Laying-Open No. 2000-114180

### DISCLOSURE OF THE INVENTION

### Problems to be Solved by the Invention

As seen from the above, for the vapor deposition apparatus, a uniform flow of the reactant gas near the substrate-to-be-processed is important in achieving high-quality crystal growth. Therefore, high-precision components are used, the components are precisely positioned and the components are assembled in the manner that provides an ideal flow of the reactant gas.

In recent years, with the purpose of providing advanced crystal growth, an approach has been employed according to which films with different characteristics are successively deposited by changing the temperature of the substrate-to-be-processed in the process of crystal growth. This approach, however, has the following problem. As shown in FIG. 7, the temperature of substrate-to-be-processed 7 is changed by varying the electric power supplied to substrate heater 10. However, the heating causes changes of all temperatures respectively of such components as susceptor 9, substrate holding member 8 and flow channel 5 in addition to substrate heater 10 and substrate-to-be-processed 7. It is rare that the components are all made of the same material. Each component has its specific coefficient of thermal expansion. Further, the components have respective dimensions that differ to a considerable degree from each other. Furthermore, the positions at which the components are relatively fixed are also different to a considerable degree. Therefore, a certain temperature change causes different dimensional changes, specifically the extent to which the dimension changes and the direction in which the dimension changes, of respective components. Thus, even if the components are precisely assembled, at a particular temperature of substrate-to-be-processed 7, so that surface 21 of substrate holding member 8 and bottom surface 20 on the inside and on the substrate holding side of flow channel 5 are relatively positioned with the precision of 0.1 mm or smaller as described herein in the section of “Background Art,” the precision cannot be kept at other temperatures of substrate-to-be-processed 7.

For example, FIG. 6 shows a certain temperature state in which surface 21 of substrate holding member 8 and bottom surface 20 on the inside and on the substrate holding side of flow channel 5 are relatively positioned to be coplanar. In contrast, FIG. 7 shows a state in which the temperature of substrate-to-be-processed 7 is increased. In this state, the amount of heat generated from substrate heater 10 increases to cause thermal expansion of susceptor 9 and substrate holding member 8, and thereby upwardly change the position of substrate-to-be-processed 7 as shown in FIG. 7. As a result, the flow of gas 15 starts to become turbulent around the upstream side of susceptor 9. In other words, the ideal positional relation of the components that is established at a certain temperature of the substrate-to-be-processed is not kept at another temperature of the substrate-to-be-processed. The resultant problem is that the ideal gas-flow state required for the vapor deposition apparatus cannot be kept continuously in a crystal growth process having a plurality of temperatures of the substrate-to-be-processed.

Similarly, with the purpose of providing advanced crystal growth, an approach has been employed according to which the air pressure (internal pressure) of the inside of the process chamber is changed in the crystal growth process. In this case as well, a change in air pressure of the inside of the process chamber causes deformation of the chamber by which the process chamber is formed, and thereby causes a change in positional relation between the internal components. Therefore, the approach also has the problem that the ideal gas flow state required for the vapor deposition apparatus cannot be maintained in the process in which the air pressure of the inside of the process chamber is changed, which is similar to the problem occurring in the case where the temperature of the substrate-to-be-processed is changed.

An object of the present invention is to provide a vapor deposition method and a vapor deposition apparatus making fine adjustments to a dynamic state in the manufacturing process to form a highly uniform epitaxial layer.

### MEANS FOR SOLVING THE PROBLEMS

A vapor deposition apparatus of the present invention is an apparatus using a reactant gas to form a thin film on a substrate in a process chamber, and the vapor deposition apparatus includes: the process chamber; a flow channel for supplying the reactant gas onto the substrate and discharging the reactant gas; a substrate holding portion holding the substrate; moving means for relatively moving the substrate holding portion and the flow channel; control means for controlling the moving means; and heating means for heating the substrate. The apparatus is characterized in that, in advance before crystal growth, the control means measures relative positions of the flow channel and the substrate holding portion under each growth condition and stores positional data concerning the measured positions, and that, based on a set growth condition as well as the stored positional data, the control means performs control of the position of the substrate holding portion or the position of the flow channel to decrease a change in relative positions of the flow channel and the substrate.

A vapor deposition method of the present invention is a deposition method using the above-described apparatus. The method is characterized in that, in advance before crystal growth, the control means measures relative positions of the flow channel and the substrate holding portion under each growth condition and stores positional data concerning the measured positions, and that, based on a set growth condition as well as the stored positional data, the control means performs control of the position of the substrate holding portion or the position of the flow channel to decrease a change in relative positions of the flow channel and the substrate.

### EFFECTS OF THE INVENTION

In accordance with the present invention, a change in relative positions of the flow channel and the substrate is small even under different growth conditions, and thus a highly uniform epitaxial growth layer can be formed.

### BRIEF DESCRIPTION OF THE DRAWINGS

FIG. 1 is a schematic illustrating a horizontal MOCVD apparatus to which the present invention is applied.

FIG. 2 is a schematic of the horizontal MOCVD apparatus to which the present invention is applied, illustrating a state in which a substrate-to-be-processed is heated to a first temperature in Example 1.

FIG. 3 is a schematic of the horizontal MOCVD apparatus to which the present invention is applied, illustrating a state after moving means is operated to make positional adjustments after the substrate-to-be-processed is heated to the first temperature in Example 1.

FIG. 4 is a schematic of the horizontal MOCVD apparatus to which the present invention is applied, illustrating a state after the internal pressure of a process chamber is changed in Example 2.

FIG. 5 is a schematic of the horizontal MOCVD apparatus to which the present invention is applied, illustrating a state after moving means is operated to make positional adjustments after the internal pressure of the process chamber is changed in Example 2.

FIG. 6 is a schematic illustrating a conventional horizontal MOCVD apparatus.

FIG. 7 is a schematic illustrating a conventional horizontal MOCVD apparatus.

FIG. 8 is a schematic illustrating a configuration of control means according to the present invention.

### DESCRIPTION OF THE REFERENCE SIGNS

1 chamber, 2 process chamber, 5 flow channel, 7 substrate, 10 heater, 12 moving means, 13 control means, 14 flange, 15 reactant gas, 16 correspondence table, 17 sensor, 20 bottom surface on the inside and on the substrate holding side of the flow channel, 21 surface of a substrate holding member, 22 crystal growth surface of the substrate

### BEST MODES FOR CARRYING OUT THE INVENTION

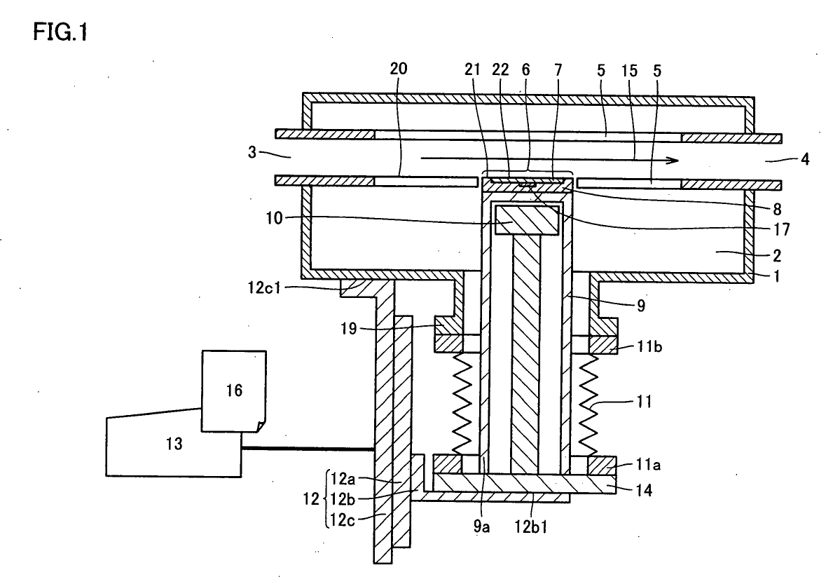

A typical example of the vapor deposition apparatus of the present invention is shown in FIG. 1. The apparatus whose representative example is a horizontal MOCVD apparatus for example uses a reactant gas 15 to form a thin film on a substrate 7. The apparatus includes a process chamber 2, a flow channel 5 for supplying reactant gas 15 onto substrate 7 and discharging the reactant gas, a substrate holding portion, moving means 12 moving the substrate holding portion or the flow channel relative to each other, control means 13 controlling moving means 12, and heating means 10 heating the substrate. In advance before crystal growth, control means 13 measures relative positions of the flow channel and the substrate holding portion under each growth condition, stores positional data concerning the measured positions, and control means 13 controls, based on a growth condition as set as well as the stored positional data, the position of the substrate holding portion or the position of the flow channel to decrease a change in relative positions of the flow channel and the substrate. Thus, according to such a growth condition as the heating temperature of the substrate or the internal pressure of the process chamber that are set for vapor deposition, the apparatus can make an adjustment to decrease a change in relative positions of the flow channel and the substrate. Therefore, the reactant gas can easily form a laminar flow on the substrate and a substantially uniform epitaxial growth layer can accordingly be formed.

For achieving the above-described effects of the present invention, it is preferable as shown in FIG. 1 to adjust the position of the substrate holding portion or the position of the flow channel so that a bottom surface 20 on the inside and on the substrate holding side of flow channel 5 and a crystal growth surface 22 of substrate 7 are almost coplanar. Here, the state of almost coplanar includes not only the state of completely coplanar but also the state of substantially coplanar that allows the reactant gas to easily form a laminar flow on the substrate and thereby allows a substantially uniform epitaxial growth layer to be formed. For example, if it is appropriate, for forming a uniform epitaxial growth layer, that bottom surface 20 on the inside and on the substrate holding side of flow channel 5 and crystal growth surface 22 of substrate 7 are displaced from each other by 100 μm to 200 μm, the state thus displaced is defined as the state of almost coplanar.

Further, according to the present invention, even in the case where more advanced crystal growth is achieved by changing the growth condition in a crystal growth process, namely at least two crystal growth conditions are provided, a turbulent flow on the substrate can be suppressed to ensure an ideal gas flow state. In addition, since the heating temperature of the substrate or the internal pressure of the process chamber included in various growth conditions has a great influence on a change in relative positional relation between the flow channel and the substrate, preferably the aforementioned temperature and pressure are included in the growth condition to be set.

In the case where a set condition of the apparatus is reached and thereafter the position of the substrate holding portion is controlled, there could occur the state where the substrate holding portion and the flow channel are caused to contact each other if the clearance between the substrate holding portion and the flow channel is small. Thus, a preferable manner is that the positional control of the substrate holding portion is completed before the set growth condition is reached, since this manner can avoid the aforementioned state, shorten the process and allow fine adjustments to be made after the positional control is once performed. The manner in which the control is completed before the set growth condition is reached includes, for example, in addition to the manner in which the positional control is completed at any time while the set condition is being reached, the manner in which the positional control is completed simultaneously with the timing at which the set condition is reached. After the set condition of the process chamber is reached, crystal growth can be started. However, a considerable time could be consumed before the position of the substrate holding portion reaches a steady state, because the leg portion for example of the substrate holding portion is far from the process chamber and thus the thermal conduction to the leg portion takes relatively long time. Accordingly, for improving the operating efficiency of the apparatus, preferably the position of the substrate holding portion is controlled before and still after the set growth condition is reached.

Positional data held in the control means is data obtained in advance before crystal growth by measuring relative positions of the flow channel and the substrate holding portion under such various crystal growth conditions as the heating temperature of the substrate and the internal pressure of the process chamber. The relative positions of the substrate holding portion and the flow channel can be represented by measuring the position for example of a flange for the sake of convenience. Further, the positional data may be stored in the form of a correspondence table. Moreover, since the control of the present invention includes manual control by an operator in addition to automatic control. Therefore, for facilitating the manual control, the positional data may be stored in the form of a graph.

As an example, data concerning relative positions of the flow channel and the substrate holding portion is indicated in Tables 1 to 5 in the form of correspondence tables. Table 1 shows data concerning the position of the flange in the case where growth conditions as set are the substrate heating temperature, the internal pressure of the process chamber and the type of the reactant gas. Table 2 shows exemplary combinations of the growth conditions shown in Table 1.

TABLE 1

| | substrate | | type of | |
|---|---|---|---|---|
| growth | heating | internal pressure | reactant | positional |
| condition | temperature | of process chamber | gas | data |
| condition 1 | temperature 1 | internal pressure 1 | gas 1 | data 1 |
| condition 2 | temperature 2 | internal pressure 1 | gas 1 | data 2 |
| condition 3 | temperature 3 | internal pressure 2 | gas 1 | data 3 |
| condition 4 | temperature 4 | internal pressure 3 | gas 2 | data 4 |

TABLE 2

| combinational | first growth | second growth | third growth |
|---|---|---|---|
| condition | condition | condition | condition |
| combinational | condition 1 | condition 2 | — |
| condition 1 | | | |
| combinational | condition 2 | condition 3 | — |
| condition 2 | | | |
| combinational | condition 2 | condition 4 | — |
| condition 3 | | | |
| combinational | condition 3 | condition 1 | condition 2 |
| condition 4 | | | |

For a manufacturing process using two or more vapor deposition conditions, the correspondence table in the form of a matrix like Table 3 is advantageous. In the correspondence table shown as Table 3, various kinds of growth conditions are specified in the first column and the first row. For example, “ab” represents the extent to which the substrate holding portion is moved (hereinafter also referred to as “difference”) in the case where growth condition “a” is changed to growth condition “b” in a manufacturing process, and is shown in the box where the column extending from growth condition “a” indicated in the first row meets the row extending from growth condition “b” indicated in the first column. Further, difference “ba” representing the difference in the case where growth condition “b” is changed to growth condition “a” is shown in the box where the column extending from growth condition “b” in the first row meets the row extending from growth condition “a” in the first column.

TABLE 3

| | a | b | c | d |
|---|---|---|---|---|
| a | — | ba | ca | da |
| b | ab | — | cb | db |
| c | ac | bc | — | dc |
| d | ad | bd | cd | — |

Moreover, in the case where the position is changed multiple times during transition to a set temperature, or the case where the position has to be changed multiple times for addressing thermal expansion for example of the leg portion of the susceptor after the vapor deposition is started, Table 4 is advantageously used that indicates time N passed from the time when the setting is changed, in the box where the first row and the first column of the table meet. Table 5 lists difference “ab” in the case where growth condition “a” is changed to growth condition “b”, and difference “ac” in the case where growth condition “a” is changed to growth condition “c”, together with time N (in minute) passed after the condition is changed. Thus, a variety of correspondence tables can be used as required.

TABLE 4

| N | a | b | c | d |
|---|---|---|---|---|
| a | — | baN | caN | daN |
| b | abN | — | cbN | dbN |
| c | acN | bcN | — | dcN |
| d | adN | bdN | cdN | — |

TABLE 5

time passed (min)

| | 1 | 2 | 3 | . . . | N |
|---|---|---|---|---|---|
| a→b | ab1 | ab2 | ab3 | . . . | abN |
| a→c | ac1 | ac2 | ac3 | . . . | acN |

The vapor deposition method of the present invention is a deposition method using the apparatus as described above. In advance before crystal growth, the control means measures relative positions of the flow channel and the substrate holding portion under each growth condition and stores positional data concerning the measured positions. Based on a set growth condition and the stored positional data, the control means controls the position of the substrate holding portion or the position of the flow channel to decrease a change in relative positions of the flow channel and the substrate. The method of the present invention can thus be used to form a highly uniform epitaxial growth layer.

### EXAMPLE 1

In this example, the horizontal MOCVD apparatus as shown in FIG. 1 was used for vapor deposition to form a thin film on a substrate by using a reactant gas in a process chamber. The vapor deposition apparatus includes process chamber 2 formed by chamber 1 in the shape of a rectangular parallelepiped, and flow channel 5 extending through process chamber 2 for supplying reactant gas 15 onto substrate-to-be-processed 7 and discharging the reactant gas. Flow channel 5 has one end provided with gas inlet 3 and the other end provided with gas outlet 4. Further, flow channel 5 has opening 6 formed at a portion located substantially centrally of the flow channel. At opening 6, substrate holding member 8 holding substrate-to-be-processed 7 mounted on the holding member 8, and susceptor 9 supporting substrate holding member 8 are provided. The substrate holding portion is comprised of substrate holding member 8 and susceptor 9. Under susceptor 9, substrate heater 10 for heating substrate-to-be-processed 7 is provided. A sensor 17 detecting the temperature of substrate-to-be-processed 7 is provided in substrate holding member 8.

These components are arranged relative to each other in the manner that bottom surface 20 on the inside and on the substrate holding side of flow channel 5 and surface 21 of substrate holding member 8 are almost coplanar. Further, in consideration of the thickness of the substrate-to-be-processed, substrate-to-be-processed 7 is mounted in a depressed portion formed in substrate holding member 8 so as to allow crystal growth surface 22 of substrate-to-be-processed 7 to be almost coplanar as well with bottom surface 20 on the inside and on the substrate holding side of flow channel 5 and with surface 21 of substrate holding member 8. A flange 14 supporting susceptor 9 and substrate heater 10 is connected to chamber 1 by which process chamber 2 is formed, via bellows 11 that is freely extendable and contractible.

Moving means 12 is provided on the outside of chamber 1. Moving means 12 has a body member 12a, a flange contact member 12b, a chamber contact member 12c, and drive means (not shown) for driving these members. While the present example used a motor as the drive means, other means may also be used. At a flange contact portion 12b1, flange 14 contacts flange contact member 12b. At a chamber contact portion 12c1, chamber 1 contacts chamber contact member 12c. With respect to body member 12a, flange contact member 12b can make a relative movement. Further, with respect to body member 12a, chamber contact member 12c can make a relative movement. As components for effecting these relative movements, a combination of a ball screw and a nut, a combination of a guide and a guide rail or a hydraulic piston for example may be employed.

With respect to chamber contact member 12c, body member 12a may be moved upward to cause flange 14 to relatively approach chamber 1. For accomplishing this approaching, flange contact member 12b may be moved upward with respect to body member 12a, or the upward movement of body member 12a with respect to chamber contact member 12c and the upward movement of flange contact member 12b with respect to body member 12a may be combined, or body member 12a may be moved downward to a certain extent with respect to chamber contact member 12c while flange contact member 12b may be moved upward to a greater extent with respect to body member 12a, or flange contact member 12b may be moved downward to a certain extent with respect to body member 12a while body member 12a may be moved upward to a greater extent with respect to chamber contact member 12c.

When body member 12a is moved downward with respect to chamber contact member 12c, flange 14 relatively recedes from chamber 1. For accomplishing this receding, various drive methods as those for the approaching may be employed and an arbitrary method can be selected from them. Thus, moving means 12 can move flange 14 in the vertical direction as seen in FIG. 1, namely the direction perpendicular to the surface of the substrate.

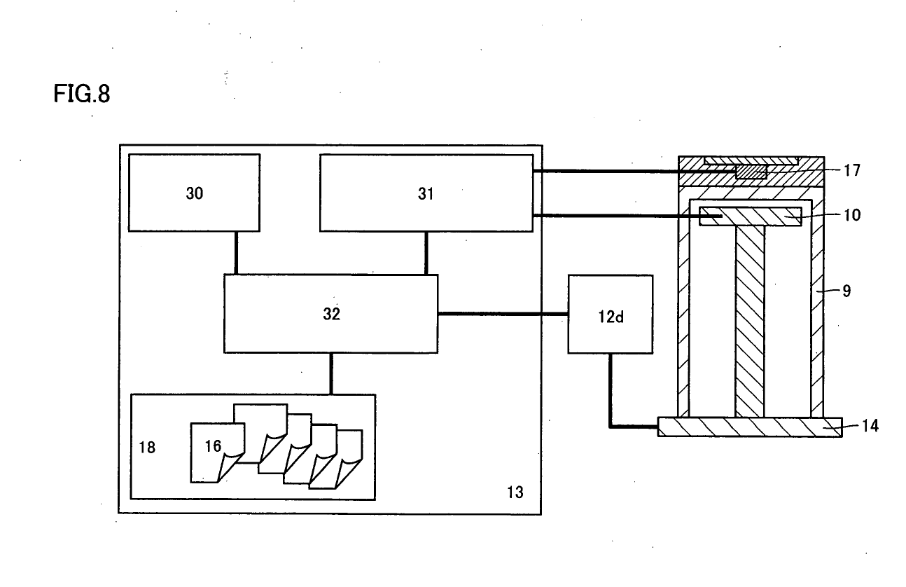

A system configuration of control means 13 controlling moving means 12 is shown in FIG. 8. Control means 13 holds therein at least positional data of flange 14 associated with set temperatures of substrate heater 10. In the present example, the positional data is represented by correspondence table 16 as shown in FIG. 8. Such a correspondence table 16 is stored in storage means 18 for example of control means 13. Control means 13 includes for example input means 30, storage means 18, temperature control means 31 and a CPU 32. Input means 30 is used to enter one film deposition condition or two or more film deposition conditions including a set temperature. Storage means 18 stores the entered film deposition condition such as the set temperature as entered, stores the temperature detected by the sensor, and stores the position of flange 14 read from any correspondence table. Temperature control means 31 controls the temperature of the substrate heater with respect to the set temperature. CPU 32 accesses the storage means to read from any correspondence table the position of flange 14 according to the temperature information. As input means 30, such means as touch panel, keyboard or numerical select dial may be used. In the present example, the keyboard was used.

Before crystal growth, in advance, relative positions of the flow channel and the substrate holding portion were measured under each of such various growth conditions as the heating temperature of the substrate, and the positional data concerning the measured positions was recorded on a correspondence table and stored. Specifically, at each temperature of substrate heater 10, the position of flange 14 was adjusted so that bottom surface 20 on the inside and on the substrate holding side of flow channel 5 is almost coplanar with crystal growth surface 22 of the substrate, and the position of flange 14 at this time was measured to record the resultant positional data on correspondence table 16. Further, adjustments for allowing bottom surface 20 on the inside and on the substrate holding side of flow channel 5 to be almost coplanar with crystal growth surface 22 of the substrate were made by applying a laser beam to each of bottom surface 20 on the inside and on the substrate holding side of flow channel 5 and substrate growth surface 22 and using information about relative positions measured by observing the reflected beams.

With respect to the vertical direction, susceptor 9 has a free end on the side where the substrate is mounted and the other end secured to flange 14. Flange 14 is secured to a leg portion 9a of susceptor 9 and also secured to one end 11a of bellows 11. Bellows 11 has the other end 11b that is closer to the substrate and that is secured to a port 19 protruding from below chamber 1. In port 19, leg portion 9a of susceptor 9 is placed. Thus, while flow channel 5 and substrate holding member 8 are very close to each other in terms of the linear distance, they are remotely related in how they are placed and structured for being secured.

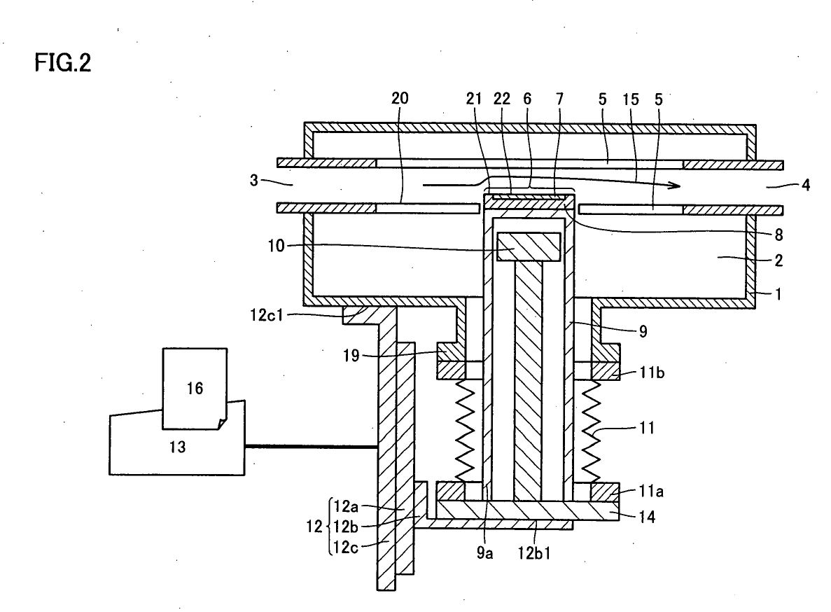

Because of the relation in placement and structure, susceptor 9 having long leg portion 9a and a high thermal expansion coefficient causes, in the case where there is no expansion/contraction of bellows 11, surface 21 of substrate holding member 8 to protrude with respect to bottom surface 20 on the inside and on the substrate holding side of flow channel 5 as the temperature rises, as show in FIG. 2. Therefore, in order to allow surface 21 of substrate holding member 8 to be almost coplanar with bottom surface 20 on the inside and on the substrate holding side of flow channel 5, the extension/contraction of the bellows is indispensable and flange 14 has to recede from chamber 1. Moving means 12 was used for this receding, and data concerning the position of flange 14 was input to the correspondence table and stored.

In the present example, a manufacturing process was selected having, as a growth condition, a first substrate temperature and a second substrate temperature. First, as shown in FIG. 1, substrate-to-be-processed 7 was conveyed to substrate holding member 8 at room temperature, and the substrate was mounted in the depressed portion of substrate holding member 8. Here, crystal growth surface 22 of the substrate was almost coplanar with bottom surface 20 on the inside and on the substrate holding side of flow channel 5 and with surface 21 of substrate holding member 8. Next, as shown in FIG. 8, input means 30 was used by an operator to enter a combination of temperature conditions as set, and thereafter CPU 32 was used to read the combinational growth condition stored in storage means 18. The combinational growth condition was roughly comprised of two stages. CPU 32 informed temperature control means 31 of information about the first set temperature, and temperature control means 31 supplied electric power to substrate heater 10 and started to take temperature information from sensor 17. Storage means 18 stored the temperature information from the sensor successively in time. Temperature control means 31 compared the first set temperature with the temperature information about the detected temperature, and accordingly controlled the amount of electric power supplied to substrate heater 10 to raise the temperature of substrate-to-be-processed 7 to the first set temperature and keep the set temperature.

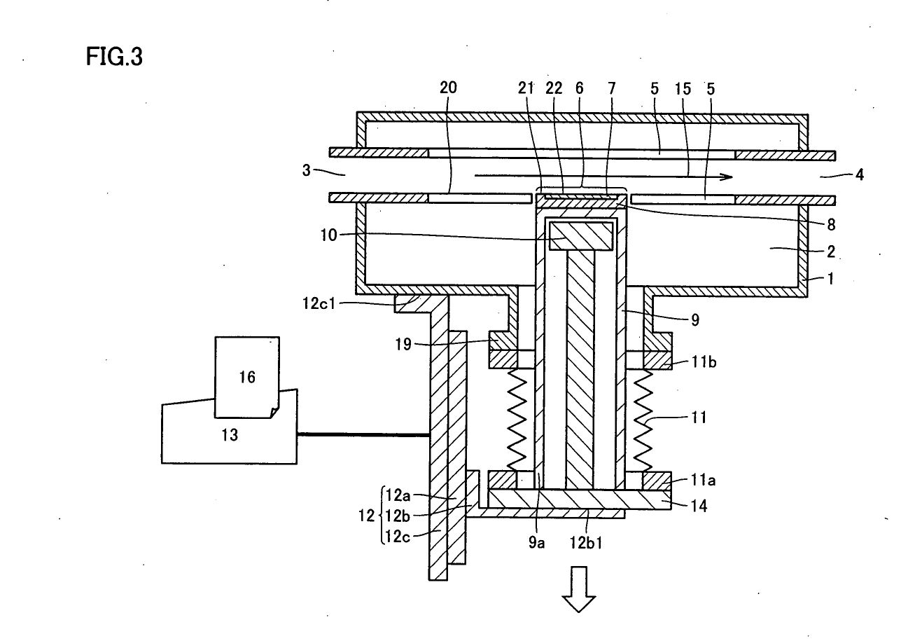

Subsequently, as shown in FIG. 2, the increased temperature of substrate-to-be-processed 7 caused respective temperatures of components therearound to also increase, and accordingly these components thermally expanded and crystal growth surface 22 of substrate-to-be-processed 7 was moved upward. Consequently, the condition that bottom surface 20 on the inside and on the substrate holding side of flow channel 5 was almost coplanar with crystal growth surface 22 of substrate-to-be-processed 7 was failed to be satisfied. In this state, if reactant gas 15 is supplied into flow channel 5, the flow of reactant gas 15 will be turbulent since substrate holding member 8 protrudes from bottom surface 20 on the inside and on the substrate holding side of flow channel 5. Thus, as shown in FIG. 8, the CPU of control means 13 accessed correspondence table 16 stored in storage means 18 to read from the correspondence table information about the position of the flange associated with the first set temperature, used the read information about the position of the flange to compare the position of the flange with information about the initial position of the flange at room temperature, informed drive means 12d of the difference (the extent to which the substrate holding portion is moved) and instructed the drive means to move the body member for example to decrease the change in relative positions of the flow channel and the substrate. Specifically, as shown in FIG. 3, the moving means was driven to move the flange downward and accordingly an adjustment could be made to allow the bottom surface on the inside and on the substrate holding side of the flow channel to be almost coplanar with the crystal growth surface of the substrate.

Then, for accomplishing vapor deposition under the first growth condition, a first reactant gas 15 was supplied from gas inlet 3 into flow channel 5, substrate heater 10 provided under susceptor 9 induced a chemical reaction for film deposition on substrate-to-be-processed 7, and accordingly a first thin film was formed on substrate-to-be-processed 7. Reactant gas 15 passing by on substrate-to-be-processed 7 was discharged from gas outlet 4. After the first film deposition was completed, the temperature of the substrate-to-be-processed was changed to the second temperature. When the temperature of the substrate-to-be-processed reached the second temperature, respective temperatures of components therearound also changed. Accordingly, respective amounts of thermal expansion of the components changed. As a result, the condition was failed to be satisfied again that the bottom surface on the inside and on the substrate holding side of the flow channel was almost coplanar with the crystal growth surface of the substrate, which was accomplished by the adjustment when the temperature of the substrate-to-be-processed was the first temperature. Then, as shown in FIG. 8, control means 13 read again from correspondence table 16 the information about the position of the flange associated with the temperature of the contained substrate heater, compared the information about the second position of the flange with the information about the first position of the flange, and the CPU instructed drive means 12d to operate by the difference (the extent to which the substrate holding portion was moved). The flange was moved and, when the temperature reached the set temperature, a second reactant gas was supplied into the apparatus to perform second film deposition. Through the above-described operation, for both of the first film deposition and the second film deposition having respective film deposition temperatures different from each other, the preferred condition that the bottom surface on the inside and on the substrate holding side of the flow channel is almost coplanar with the crystal growth surface of the substrate could be satisfied. Thus, even in such an advanced process changing the vapor deposition condition, a highly uniform epitaxial growth layer could be formed.

It is noted that the present example makes the adjustment to move the substrate and thereby allows the bottom surface on the inside and on the substrate holding side of the flow channel to be almost coplanar with the crystal growth surface of the substrate. However, the flow channel may be moved instead to achieve a similar effect.

Further, the present example shows the case where the thermal expansion causes a positional displacement of the substrate and the flow channel from each other in the direction perpendicular to the surface of the substrate. However, even in the case where the positional displacement occurs in the direction in parallel with the substrate surface, the substrate or the flow channel may be moved as done for the perpendicular displacement, to keep the relative positions of the substrate and the flow channel.

### EXAMPLE 2

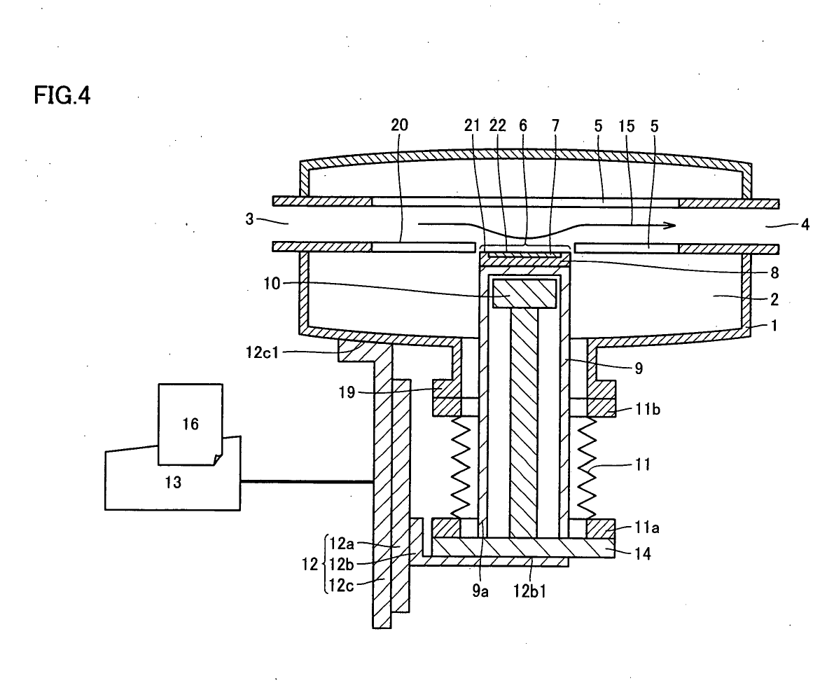

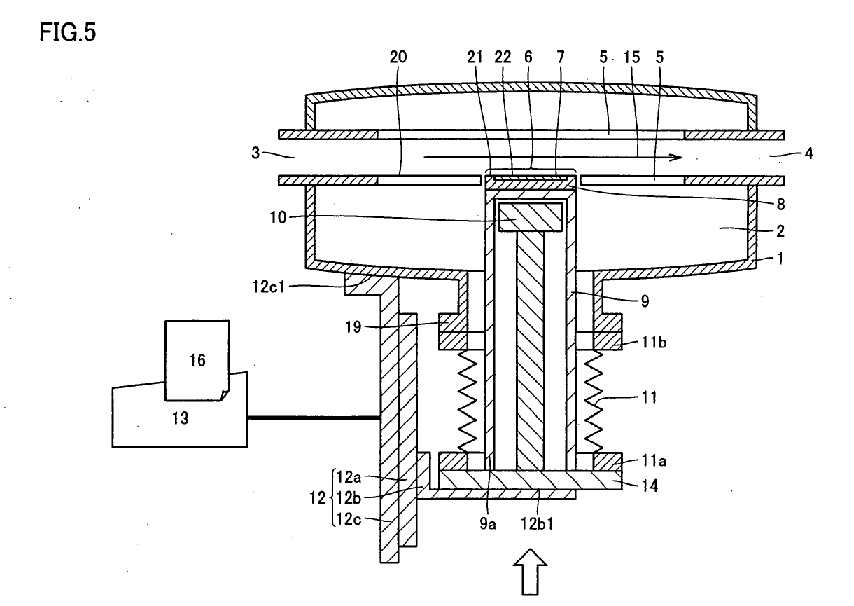

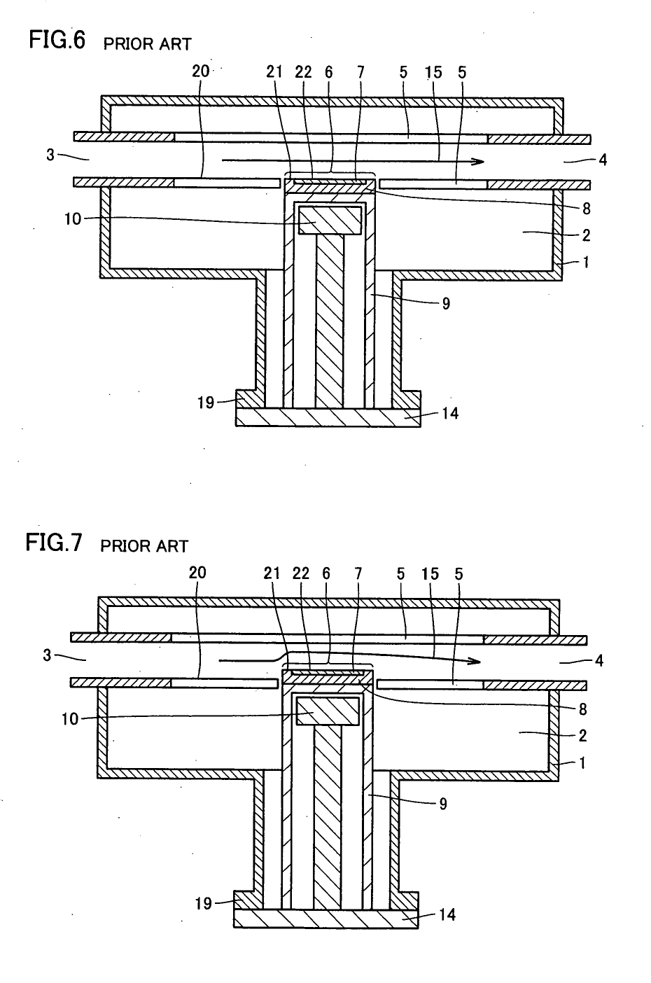

In the present example, a manufacturing process was selected having, as a growth condition, a first internal pressure of the process chamber and a second internal pressure of the process chamber. First, a horizontal MOCVD apparatus similar to that in Example 1 was used and, before crystal growth in advance, relative positions of the flow channel and the substrate holding portion at various internal pressures of the process chamber were measured. The positional data concerning the measured positions was recorded on correspondence table 16 and stored. The position of the substrate holding portion was controlled in the following way. For example, as shown in FIG. 4, the pressure in process chamber 2 was set at a certain internal pressure and accordingly chamber 1 by which process chamber 2 was formed expanded due to a pressure difference between the set internal pressure 1 and the atmospheric pressure. Thus, the positional relation between components in chamber 1 was changed. Consequently, the position of crystal growth surface 22 of substrate-to-be-processed 7 moved downward and thus bottom surface 20 on the inside and on the substrate holding side of flow channel 5 was failed to be almost coplanar with crystal growth surface 22 of substrate-to-be-processed 7. Then, as shown in FIG. 8, since the positional data concerning the positions of flange 14 at various internal pressures of process chamber 2 was measured and stored in advance before the crystal growth, control means 13 used correspondence table 16 storing such positional data to drive moving means 12 based on the set growth condition and the stored positional data, as shown in FIG. 5, and moved flange 14 upward to control the position of the substrate holding portion and decrease a change in relative positions of the flow channel and the substrate. Accordingly, the adjustment could be made to allow bottom surface 20 on the inside and on the substrate holding side of the flow channel to be almost coplanar with crystal growth surface 22 of the substrate. Thereafter, the first film deposition process was performed as done in the example.

Next, the pressure of process chamber 2 was changed to the second internal pressure for a second film deposition process to be performed. Then, chamber 1 by which process chamber 2 was formed deformed due to a difference between its pressure and the atmospheric pressure. Accordingly, the positional relation between internal components of the chamber changed again. As a result, the condition was failed to be satisfied again that the bottom surface on the inside and on the substrate holding side of flow channel 5 was almost coplanar with the crystal growth surface of substrate-to-be-processed 7, which was accomplished by the adjustment made when the internal pressure of process chamber 2 was the first internal pressure. Then, as shown in FIG. 8, control means 13 drove the moving means based on the set internal pressure of process chamber 2 as well as the stored positional data of the flange, moved the flange, and controlled the position of the substrate holding portion to decrease a change in relative positions of the flow channel and the substrate. Accordingly, the bottom surface on the inside and on the substrate holding side of the flow channel was almost coplanar with the crystal growth surface of the substrate-to-be-processed. After this, as in Example 1, second film deposition was performed. Thus, in such an advanced process changing the vapor deposition condition, a highly uniform epitaxial growth layer could be formed.

It is noted that the present example moves the substrate to make the adjustment for allowing the bottom surface on the inside and on the substrate holding side of the flow channel to be almost coplanar with the crystal growth surface of the substrate. However, the flow channel may be moved instead to achieve a similar effect.

Further, the present example shows the case where a pressure change causes a positional displacement of the substrate and the flow channel relative to each other in the direction perpendicular to the surface of the substrate. However, even in the case where the positional displacement occurs in the direction in parallel with the substrate, the substrate or the flow channel may be moved as done for the perpendicular displacement to keep the relative positions of the substrate and the flow channel.

The embodiments and examples herein disclosed should be considered as those presented by way of illustration in every respect, not by way of limitation. It is intended that the scope of the present invention is not defined by the foregoing description, but by claims, and includes all variations equivalent in meaning and scope of the claims.

1. A vapor deposition method using a reactant gas to form a thin film on a substrate in a process chamber,
said vapor deposition method using an apparatus including:
the process chamber;
a flow channel for supplying the reactant gas onto said substrate and discharging the reactant gas;
a substrate holding portion holding said substrate;
moving means for relatively moving the substrate holding portion and said flow channel;
control means for controlling the moving means; and
heating means for heating said substrate, wherein
in advance before crystal growth, said control means measures relative positions of the flow channel and the substrate holding portion under each growth condition and stores positional data concerning the measured positions, and
based on a set growth condition as well as the stored positional data, said control means performs control of the position of the substrate holding portion or the position of the flow channel to decrease a change in relative positions of the flow channel and the substrate.

2. The vapor deposition method according to claim 1, wherein the position of the substrate holding portion or the position of the flow channel is controlled so that a bottom surface on the inside and on a substrate holding side of the flow channel is almost coplanar with a crystal growth surface of the substrate.

3. The vapor deposition method according to claim 1, wherein at least two growth conditions are set.

4. The vapor deposition method according to claim 1, wherein said growth condition includes a heating temperature of the substrate.

5. The vapor deposition method according to claim 1, wherein said growth condition includes an internal pressure of the process chamber.

6. The vapor deposition method according to claim 1, wherein said control means completes said control before the set growth condition is reached.

7. The vapor deposition method according to claim 1, wherein said control means performs said control before and still after the set growth condition is reached.

8. A vapor deposition apparatus using a reactant gas to form a thin film on a substrate in a process chamber, comprising:
the process chamber;
a flow channel for supplying the reactant gas onto said substrate and discharging the reactant gas;
a substrate holding portion holding said substrate;
moving means for relatively moving the substrate holding portion and said flow channel;
control means for controlling the moving means; and
heating means for heating said substrate, wherein
in advance before crystal growth, said control means measures relative positions of the flow channel and the substrate holding portion under each growth condition and stores positional data concerning the measured positions, and
based on a set growth condition as well as the stored positional data, said control means performs control of the position of the substrate holding portion or the position of the flow channel to decrease a change in relative positions of the flow channel and the substrate.
